(19) United States
(12) Patent Application Publication
(10) Pub. No.: US 2013/0048064 A1
(43) Pub. Date: Feb. 28, 2013

(54) Interconnections for Mechanically Stacked Multijunction Solar Cells

(71) Applicants: William Edwin McMAHON, Denver, CO (US); James Scott WARD, Golden, CO (US); Chieh-Ting LIN, Santa Barbara, CA (US); Mark W. WANLASS, Evergreen, CO (US)

(72) Inventors: William Edwin McMAHON, Denver, CO (US); James Scott WARD, Golden, CO (US); Chieh-Ting LIN, Santa Barbara, CA (US); Mark W. WANLASS, Evergreen, CO (US)

(73) Assignee: ALLIANCE FOR SUSTAINABLE ENERGY, LLC, Golden, CO (US)

(21) Appl. No.: 13/597,156

(22) Filed: Aug. 28, 2012

Related U.S. Application Data
(60) Provisional application No. 61/528,668, filed on Aug. 29, 2011.

(51) Int. Cl. H01L 31/0725

(52) U.S. Cl. 136/255

(57) ABSTRACT

Mechanically stacked multijunction solar cells are provided. In one embodiment, a mechanically stacked, multijunction solar cell comprises: a first solar cell having a first bandgap; a second solar cell having a second bandgap; and a plurality of spaced apart metal pillars sandwiched between the first solar cell and the second solar cell.

### CROSS-REFERENCE TO RELATED APPLICATIONS

This application claims the benefit of and priority to U.S. Provisional Application No. 61/528,668, filed on Aug. 29, 2012 and entitled “MECHANICALLY STACKED MULTIJUNCTION SOLAR CELLS”, which is incorporated herein by reference in its entirety.

### GOVERNMENT LICENSE RIGHTS

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

High-efficiency multijunction solar cells are fabricated from materials with different band gaps. In a typical multijunction solar cell, individual single-junction cells with different energy band gaps (Eg) are stacked on top of each other. Sunlight falls first on the material having the largest band gap, and the highest energy photons are absorbed. Photons not absorbed in the first or top cell are transmitted to the second cell, which absorbs the higher energy portion of the remaining solar radiation, while remaining transparent to the lower energy photons. In theory, any number of cells can be used in multijunction devices. There is a desire to make multijunctions solar cells with four or more cells. However, to date, only two or three cells have been functionally designed.

Multijunction solar cells may be made in one of two ways, monolithically or mechanically stacked. Monolithic multijunction solar cells are typically made by sequentially growing all the necessary layers of materials for two or more cells and the necessary interconnection between the cells. Ideally these materials can be grown epitaxially, but for some material combinations, this is impossible or undesirable. Growing four solar cell junctions on the same substrate requires lattice-mismatched epitaxy, and the associated dislocations can degrade the performance of the fourth solar cell, such that the resulting device performs more poorly than existing three junction devices.

Another approach is to spectrally split the light and send the spectrally split light to different junctions grown on different substrates. This approach is inherently complex, and optical losses may reduce the device efficiency to below the level of existing three junction solar cell devices.

A third option is direct semiconductor bonding used to bond together solar cells that have been grown on different substrates. To date, bonds with adequate electrical conductivity and mechanical integrity for concentrated photovoltaics (CPV) applications do not exist.

Yet another solution is to mechanically stack sub-cells in such a manner that the entire stack of sub-cells converts incident light into electricity. Many different combinations of solar cells have been created using mechanical stacks. However, most mechanically stacked multijunction solar cells have poor thermal conductivity and optical coupling between the upper and lower subcells. In principle, this approach enables the use of a wide range of materials and therefore, very high conversion efficiencies. In practice, it is important to minimize the electrical resistivity and optical reflectivity losses at each bonded interface in the mechanical stack. For most applications, it is also important that heat from the upper solar cells can easily pass through the bonded interface and lower solar cells to reach a heat sink beneath the lower cells.

The foregoing examples of the related art and limitations related therewith are intended to be illustrative and not exclusive. Other limitations of the related art will become apparent to those of skill in the art upon a reading of the specification and a study of the drawings.

### BRIEF DESCRIPTION OF THE DRAWINGS

Exemplary embodiments presented in this disclosure can be more easily understood and further advantages and uses thereof more readily apparent, when considered in view of the description of the following figures in which:

FIG. 1 shows a top view of a solar cell with an interfacial metallization grid having substantially parallel lines of metallization;

FIG. 2 illustrates a side cut-away view of a solar cell with an interfacial metallization grid having substantially parallel lines of metallization sandwiched between two solar cells;

FIG. 3 shows a top view of a solar cell with an interfacial metallization pattern of spaced-apart pillars;

FIG. 4 shows a side cut-away view of a solar cell with an interfacial metallization pattern of spaced-apart pillars sandwiched between two solar cells;

FIG. 5 shows a side cut-away view of a solar cell with an interfacial metallization pattern of spaced-apart pillars sandwiched between two solar cells, including an optically transparent bonding material;

FIG. 6 shows a side cut-away view of a solar cell with an interfacial metallization pattern of spaced-apart pillars sandwiched between two solar cells, including layers of optically transparent material;

FIG. 7 shows a side cut-away view of a solar cell with an interfacial metallization pattern of spaced-apart pillars sandwiched between two solar cells, including an index-matched semiconductor material as an optical coupling material with an air gap; and

FIGS. 8a-j illustrate a fabrication sequence for fabricating a solar cell with an interfacial metallization pattern of spaced-apart pillars sandwiched between two solar cells.

In accordance with common practice, the various described features are not drawn to scale but are drawn to emphasize features relevant to the presented embodiments. Reference characters denote like elements throughout figures and text.

### DETAILED DESCRIPTION

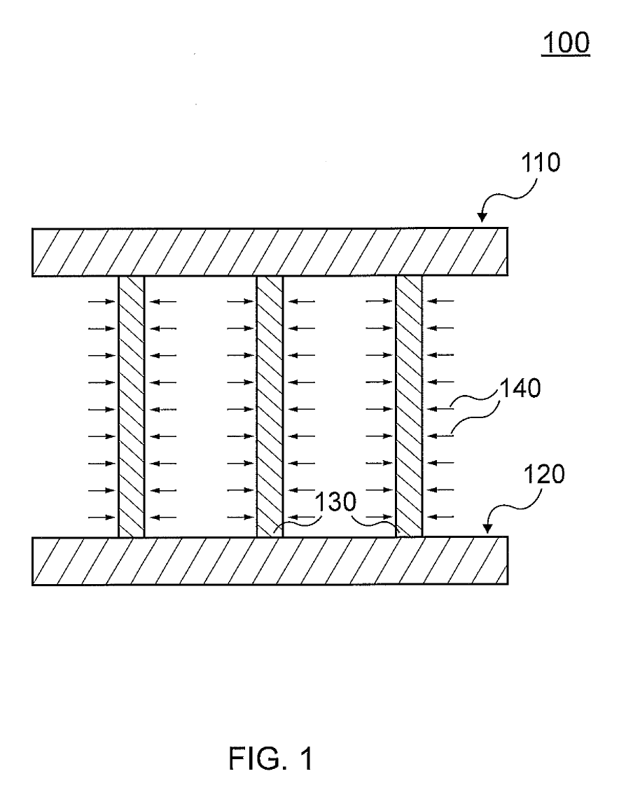

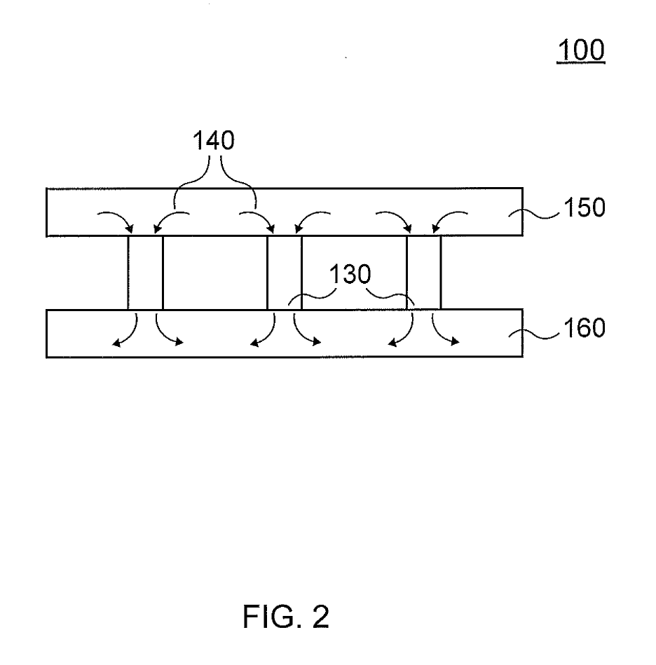

FIG. 1 shows a partial top view of a mechanically stacked multijunction solar cell 100 with an interfacial metallization grid having substantially parallel lines of metallization 130 that intersect with bus bars 110 and 120 at or near the edges of solar cell 100. FIG. 2 illustrates a side cut-away view of a mechanically stacked multijunction solar cell 100 with an interfacial metallization grid having substantially parallel lines of metallization 130 sandwiched between an upper solar cell 150 and a lower solar cell 160. Arrows 140 show example of potential current movement in this embodiment of a mechanically stacked multijunction solar cell 100 with interfacial metallization grid having substantially parallel lines of metallization 130. One of the issues of this embodiment is to minimize optical obscuration of the metallization lines 130. In principal, narrow metal lines or fingers at the interface could be places in the shadow of the fingers on the top surface of the top cell stack, giving good electrical conductivity with no additional shadow loss, beyond that of the top surface grid fingers. In practice, the optical obscuration footprint of the interfacial metal fingers or lines 130 can be much wider than that of the overlying top-surface grid fingers.

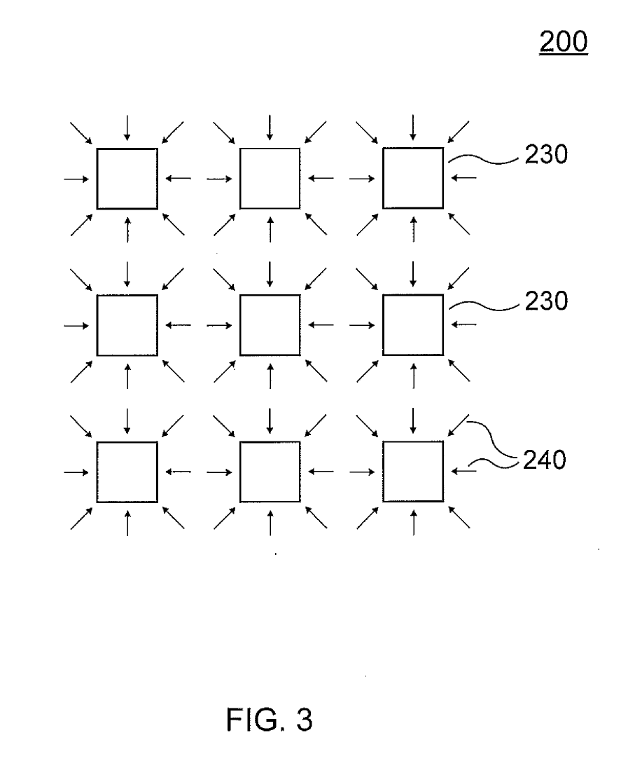

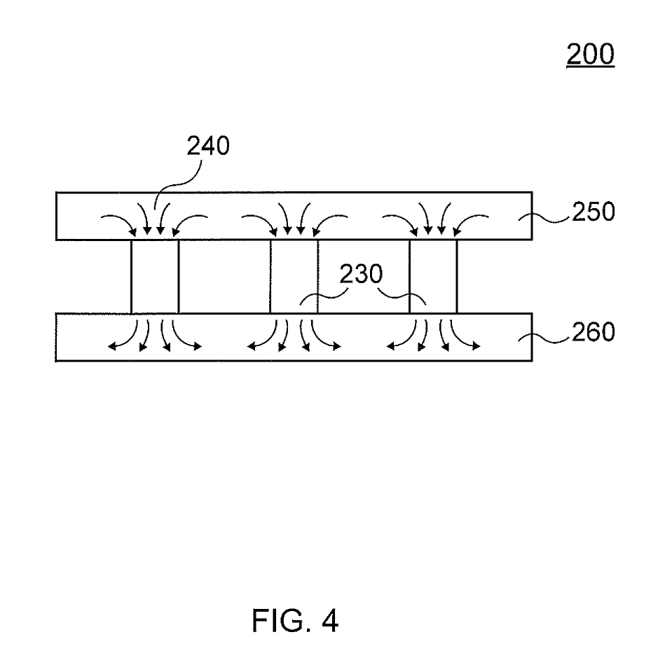

FIG. 3 shows a partial top view of a mechanically stacked, multijunction solar cell 200 with an interfacial metallization pattern of spaced-apart pillars 230. FIG. 4 shows a partial side, cut-away view of the mechanically stacked, multijunction solar cell 200 of FIG. 3 with an interfacial metallization pattern of spaced-apart pillars 230 sandwiched between an upper solar cell 250 and a lower solar cell 260. This mechanically stacked solar cell 200 arrangement with an array of metal pillars 230 may reduce the optical losses for two-terminal configurations, in which external current-collecting contacts to a load are only made to the very top and bottom of the mechanical stack 200, and no external current-collecting contact is made to the bonded interface layer. The array of metal pillars 230 provides an improved compromise between minimal shadow loss and minimal electrical resistivity. The advantages of an array of metal pillars 230 may be even greater for the non-normal light paths inherent to concentrating photovoltaic (CPV) applications. In a two-terminal device, lateral current conduction by the metal (parallel to the interface) is unnecessary, and providing for it may incur unnecessary optical obscuration for the non-normal light paths inherent to concentrating photovoltaics (CPV) applications.

In the array-of-metal-pillars arrangement 230, each pillar may carry current (shown as arrows 240) collected from a small portion of the total area. As the spacing between pillars 230 is decreased, the total amount of current collected by each pillar decreases. Because of current-crowding, perimeter length of pillars affects R series. Therefore, the optimal shape may be a rectangular cross section, as shown. However, the pillars 230 may be any shape, such as circular, oval, triangular, discontinuous line segments, etc.

An interfacial grid line array (such as shown at 100) may appear to be optimal, because it maximizes the amount of metal at the interface with no apparent shadow loss, assuming a perfect geometry with no alignment or lithography related losses and substantially perfect normal-incident light. However, inclusion of shadow losses, and therefore, loss of light and subsequent current to bottom cell(s), due to lithography and alignment errors may favor an interfacial pillar geometry (such as shown at 200).

Specifically, a pillar arrangement has a similar or lower shadow loss than a grid line arrangement. For example, a 20×20 μm pillar is significantly less sensitive to alignment and fabrication errors than a 5 μm wide grid line. In particular, the sum of the errors may raise the effective shadow loss of each grid line significantly (from 5 μm to 8-11 μm in the above example). For a concentrator grid with a shadow loss of 4% in the top cell(s), the shadow loss of the bottom cell(s) may be in the order of 6 to 8.8%, for normal incidence light. For non-normal light (as from a lens), the shadow loss for the bottom cell may be much higher. Also, a 1 μm mis-alignment of grid lines reduces bonding area by 1 μm from 5 μm to 4 μm, which may result in a 20% reduction. However, for a 20×20 μm pillar, a 1 μm mis-alignment may have less shadow losses and maintain a good bonding area. Accordingly, the pillar arrangement will have a greater metal-to-metal overlap contact area for bonding. The shadow loss for non-normal light should be less for pillars than for grid lines under non-normal light conditions, such as from a lens. Furthermore, the 5 μm wide grid lines may be unrealistic. If 10 μm grid lines are required, then pillars will have a significantly smaller shadow loss.

Although most of the above summary concerns light in a normal-incidence geometry, it may be noted that non-normal light, as from a lens, will likely favor a pillar arrangement. Specifically, given substantially equal shadow loss for normal incidence, pillars should have lower shadow loss for off-normal incidence. At high concentrations, the range of angles can be large, up to approximately 42° for glancing incidence light. This embodiment may minimize electrical and optical losses for a configuration in which metal interconnects are used to carry electrical current from an upper cell(s) across a bonded interface to a lower cell(s).

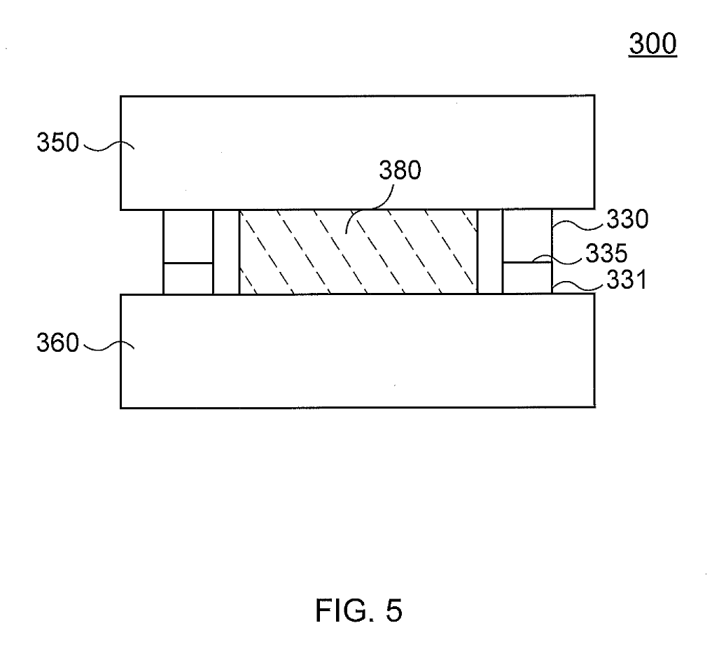

FIG. 5 shows a side cut-away view of a mechanically stacked, multijunction solar cell 300 with an interfacial metallization pattern of spaced-apart pillars 330 and 331 sandwiched between an upper solar cell 350 and a lower solar cell 360, including an optically transparent bonding material 380. In this embodiment, the metal-to-metal bonds 335 of pillars 330 and 331 are for strength and current conduction, while the optically transparent bonding material 380 supports optical coupling within the mechanically stacked, multijunction solar cell 300. The optically transparent bonding material 380 may be a single material for optical coupling, such as SiO₂, SiN, TiO₂, etc. This embodiment attempts to fill the voids between the metal-to-metal pillar interconnects 330 and 331 with a material that provides optical and thermal coupling across the bonded interface.

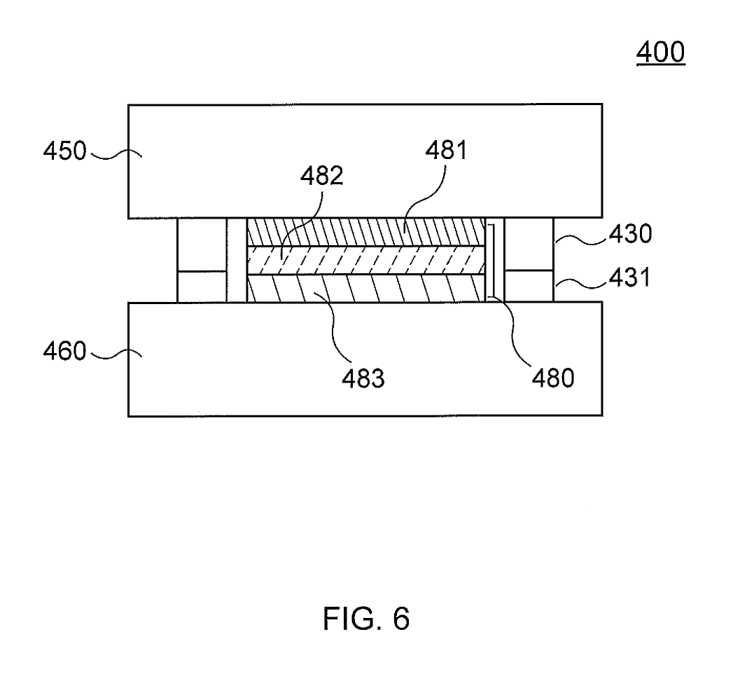

FIG. 6 shows a side cut-away view of a mechanically stacked, multijunction solar cell 400 with an interfacial metallization pattern of spaced-apart pillars 430 and 431 sandwiched between a top solar cell 450 and a bottom solar cell 460, including layers 481, 482, 483 of optically transparent material 480. The layers 481, 482, 483 may be a stack of materials optimized for maximizing optical transmission of light exiting the upper solar cell 450 to the lower solar cell 460 for absorption and conversion to electricity. The optically transparent bonding material 480 may include a very slight air gap, which may reflect unusable light. This embodiment may utilize epitaxially grown filler material 480, such as a semiconductor material, to fill the space between the metal-to-metal pillars 430 and 431. The filler material 480 may be grown on the bottom surface of the top solar cell 450 and/or on the top surface of the bottom solar cells 460. The filler material 480 may be etched, such as with photolithography, to create vias into which the metal contacts to both the upper solar cell 450 and the lower solar cells 460 may be deposited. The upper solar cell 450 and the lower solar cell 460 may then be brought together and bonded.

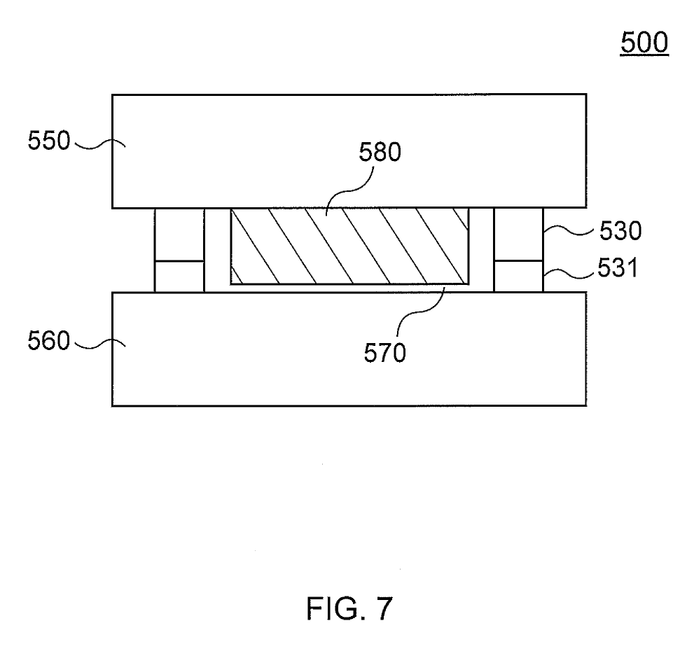

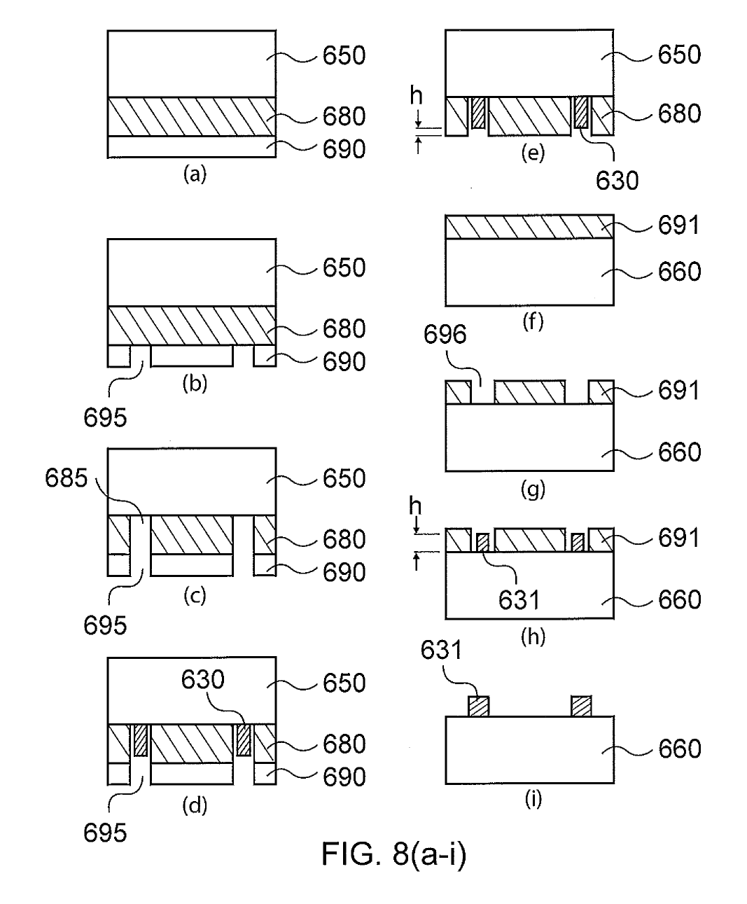

FIG. 7 shows a side cut-away view of a mechanically stacked, multijunction solar cell 500 with an interfacial metallization pattern of spaced-apart metal on thin metal pillars 530 and 531 sandwiched between an upper solar cell 550 and a lower solar cell 560, including an index-matched semiconductor material 580 as an optical coupling material that may include an air gap 570. This embodiment may simplify lithography, eliminate the need for growing optical coupling materials or stacks, and may give good optical transmission for very thin air gaps. The thickness of the thin metal pillars 530 and 531 can be tuned during fabrication. The index-matched semiconductor material 580 may be grown during epitaxial growth or during fabrication.

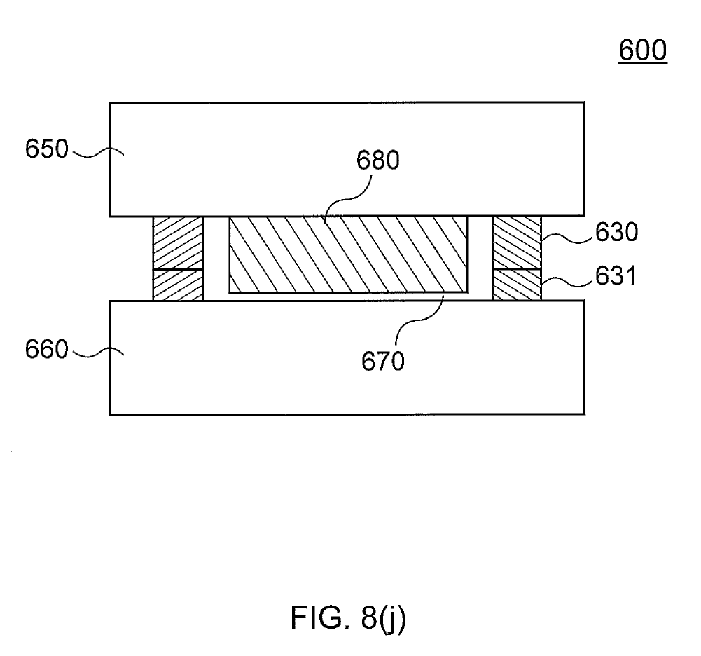

FIGS. 8a-j illustrate a fabrication sequence for fabricating a mechanically stacked, multijunction solar cell 600 with an interfacial metallization pattern of spaced-apart, metal-to-metal pillars 630 and 631, sandwiched between an upper solar cell 650 and a lower solar cell 660, including an optical coupling material 680 that may include a small air gap 670. During fabrication, a layer of photoresist 690 may be added to an optical coupling layer 680 and a top solar cell 650, as shown in FIG. 8a. It should be noted that the optical coupling layer 680 may be grown epitaxially, such as on the top solar cell 650. The photoresist 690 may be selectively removed at predetermined locations 695 for receiving metal pillars, as shown in FIG. 8b. The optical coupling layer 680 is then selectively removed by any known method, such as by etching with photolithography to create vias onto which metal contacts to the upper solar cell 650 may be deposited, as shown in FIG. 8c. Metal 630 is then deposited into the vias 695, as shown in FIG. 8d. The photoresist is then removed, as shown in FIG. 8e. With respect to the bottom solar cell 660, a photoresist layer 691 is deposited, as shown in FIG. 8f. The photoresist is selectively removed to form vias 696, as shown in FIG. 8g. Metal 631 is deposited in the vias 696, as shown in FIG. 8h. The photoresist layer 691 is then removed, as shown in FIG. 8i. The upper solar cell 650 and the lower solar cell 660 are then brought together and bonded, typically by heating or annealing, as shown in FIG. 8j. It should be noted that element h, shown in FIGS. 8e and 8h, may be adjusted to help with height mismatch in the fabrication process. Another method is to add in a small gap between the optically transparent material and the lower solar cell, as shown in FIGS. 7 and 8j.

The geometry and dimensions are such that metal-to-metal bonds are made between the upper and lower contacts, and a filler-to-semiconductor or filler-to-filler bond is made over the rest of the interface. Because the metal-to-metal bonds carry electrical current between the upper and lower solar cells, the filler material does not need to perform this function. The filler material, and bonds to it, must, however, be optically transparent to light used by the lower solar cell(s) and have excellent thermal conductivity. In order to accomplish excellent thermal conductivity, the filler material must be in physical contact to the material above and below it. However, physical contact is sufficient, and a strong bond is not necessary. Also, to assist with fabrication limitations, a small air gap is tolerable optically. However, for good thermal conductivity between the solar cells, physical contact between the optical transparent materials and the upper and lower solar cells may be an improvement over an air gap.

While a number of exemplary aspects and embodiments have been discussed above, those of skill in the art will recognize certain modifications, permutations, additions and sub combinations thereof. For example, the metal pillars do not necessarily have to be metal. They can be of any material which can be bonded together with excellent electrical conductivity. It is therefore intended that the following appended claims and claims hereafter introduced are interpreted to include all such modifications, permutations, additions and sub-combinations as are within their true spirit and scope.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the embodiments described herein. Therefore, it is manifestly intended that this invention be limited only by the claims and the equivalents thereof.

What is claimed is:

1. A mechanically stacked, multijunction solar cell comprising:
a first solar cell having a first bandgap;
a second solar cell having a second bandgap; and
a plurality of spaced apart metal pillars sandwiched between the first solar cell and the second solar cell.

2. The mechanically stacked, multijunction solar cell according to claim 1, further including an optically transparent bonding material between the plurality of spaced apart metal pillars, wherein the optically transparent bonding material is also sandwiched between the first solar cell and the second solar cell.

3. The mechanically stacked, multijunction solar cell according to claim 2, wherein the optically transparent bonding material comprises SiO₂.

4. The mechanically stacked, multijunction solar cell according to claim 2, wherein the optically transparent bonding material comprises SiN.

5. The mechanically stacked, multijunction solar cell according to claim 2, wherein the optically transparent bonding material comprises TiO₂.

6. The mechanically stacked, multijunction solar cell according to claim 2, wherein the optically transparent bonding material comprises more than one layer of optically transparent materials, wherein the more than one layer of optically transparent materials is configured to optimize optical transmission.

7. The mechanically stacked, multijunction solar cell according to claim 2, wherein the optically transparent bonding material comprises more than one layer of optically transparent materials, wherein the more than one layer of optically transparent materials is configured to reflect unusable light.

8. The mechanically stacked, multijunction solar cell according to claim 2, wherein the optically transparent bonding material comprises more than one layer of optically transparent materials, wherein the more than one layer of optically transparent materials includes an air gap between the more than one layer of optically transparent materials and one of either the first solar cell or the second solar cell.

9. The mechanically stacked, multijunction solar cell according to claim 2, wherein the optically transparent bonding material comprises more than one layer of optically transparent materials, wherein the more than one layer of optically transparent materials comprises an index-matched semiconductor material.

10. The mechanically stacked, multijunction solar cell according to claim 2, wherein the optically transparent bonding material comprises more than one layer of optically transparent materials, wherein the more than one layer of optically transparent materials comprises an epitaxially grown, index-matched semiconductor material.

11. The mechanically stacked, multijunction solar cell according to claim 2, wherein the optically transparent bonding material comprises an index-matched semiconductor material.

12. The mechanically stacked, multijunction solar cell according to claim 11, wherein the index-matched semiconductor material comprises GaInP.

13. The mechanically stacked, multijunction solar cell according to claim 11, wherein the index-matched semiconductor material comprises GaAs.

14. The mechanically stacked, multijunction solar cell according to claim 11, wherein the index-matched semiconductor material comprises AlGaAs.

15. The mechanically stacked, multijunction solar cell according to claim 11, wherein the index-matched semiconductor material comprises GaAlP.

16. The mechanically stacked, multijunction solar cell according to claim 2, wherein the optically transparent bonding material comprises an epitaxially grown, index-matched semiconductor material.

17. The mechanically stacked, multijunction solar cell according to claim 2, wherein an optically transparent bonding material comprising a GaInP₂ material is grown on the first solar cell and an optically transparent material comprising a InP material is grown on the second solar cell, wherein the GaInP₂ is bonded to the InP material.

18. The mechanically stacked, multijunction solar cell according to claim 16, wherein the epitaxially grown, index-matched semiconductor material comprises a layer of GaInP₂ material grown on the first solar cell and a layer of InP material grown on the second solar cell.

19. A mechanically stacked, multijunction solar cell comprising:
a first solar cell having a first bandgap;
a second solar cell having a second bandgap;
an interfacial metallization grid sandwiched between the first solar cell and the second solar cell; and
an optically transparent bonding material also sandwiched between the first solar cell and the second solar cell, wherein the optically transparent bonding material comprises an index-matched semiconductor material.

20. The mechanically stacked, multijunction solar cell according to claim 19, wherein the optically transparent bonding material comprises an epitaxially grown, index-matched semiconductor material.

21. The mechanically stacked, multijunction solar cell according to claim 20, wherein the epitaxially grown, index-matched semiconductor material comprises a layer of GaInP₂ material grown on the first solar cell and a layer of InP material grown on the second solar cell.

22. The mechanically stacked, multijunction solar cell according to claim 19, wherein an optically transparent bonding material comprising a GaInP₂ material is grown on the first solar cell and an optically transparent material comprising a InP material is grown on the second solar cell, wherein the GaInP₂ is bonded to the InP material.
